(19) United States
(12) Patent Application Publication
(10) Pub. No.: US 2012/0286114 A1
(43) Pub. Date: Nov. 15, 2012

(54) APPARATUS TO ATTACH PORTABLE ELECTRONIC DEVICES TO SPORTS EQUIPMENT

(76) Inventors: Marty R. Jertson, Phoenix, AZ (US); Brad D. Schweigert, Anthem, AZ (US)

(21) Appl. No.: 13/246,663

(22) Filed: Sep. 27, 2011

Related U.S. Application Data
(63) Continuation-in-part of application No. 29/391,647, filed on May 11, 2011, now Pat. No. D663947.
Application No. 29/391,647 is a continuation-in-part of application No. 29/391,657, filed on May 11, 2011, now Pat. No. D648119.
(60) Provisional application No. 61/485,549, filed on May 12, 2011.

(51) Int. Cl. H05K 7/00; F16B 2/06

(52) U.S. Cl. 248/219.4; 248/226.11

(57) ABSTRACT

Embodiments of apparatus to attach portable electronic devices to sports equipment are generally described herein. Other embodiments may be described and claimed.

### CROSS REFERENCE

This patent application is a continuation-in-part application claiming priority to U.S. patent application Ser. No. 29/391,647 filed on May 11, 2011 and U.S. patent application Ser. No. 29/391,657 filed on May 11, 2011. This application claims the benefits of U.S. Provisional Application 61/485,549 filed on May 12, 2011. The disclosures of the referenced applications are incorporated herein by reference.

### TECHNICAL FIELD

The present disclosure relates generally to sport accessories, and more particularly, to apparatus to attach portable electronic devices to sports equipment.

### BACKGROUND

In golf, some training devices may be an integral part of a golf club (i.e., built-in). That is, the golf club may not be readily used for play in a round of golf. Alternatively, other training devices may only function as a golf training device such that the training device may not be used for other purposes. Instead of the types of training device for golf mentioned above, individuals may want use already-owned and/or everyday-used portable electronic devices as a training device for golf.

### BRIEF DESCRIPTION OF THE DRAWINGS

FIG. 1 depicts a front perspective view of an example portable electronic device holder according to an embodiment of the apparatus and articles of manufacture described herein.

FIG. 2 depicts a back perspective view of an example portable electronic device holder of FIG. 1.

FIG. 3 depicts a front view of the example portable electronic device holder of FIG. 1.

FIG. 4 depicts a back view of the example portable electronic device holder of FIG. 1.

FIG. 5 depicts a first end view of the example portable electronic device holder of FIG. 1.

FIG. 6 depicts a second end view of the example portable electronic device holder of FIG. 1.

FIG. 7 depicts a first side view of the example portable electronic device holder of FIG. 1.

FIG. 8 depicts a second side view of the example portable electronic device holder of FIG. 1 engaging a golf club shaft.

FIG. 9 depicts a bottom view of the example portable electronic device holder of FIG. 1 engaging a golf club shaft.

FIG. 10 depicts a front view of the example portable electronic device holder of FIG. 1 engaging a portable electronic device.

FIG. 11 depicts a visual representation of the example portable electronic device holder of FIG. 1 engaging a golf club.

### DESCRIPTION

In general, apparatus, methods, and articles of manufacture associated with a portable electronic device holder are described herein. The methods, apparatus, and articles of manufacture described herein are not limited in this regard.

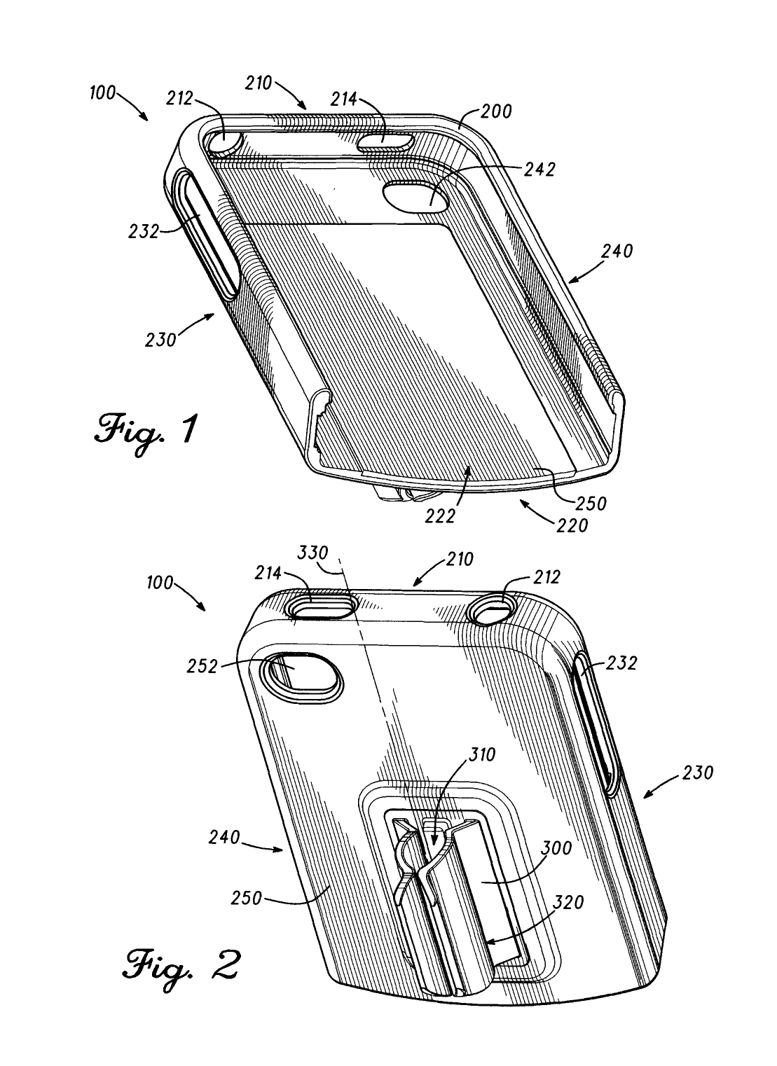

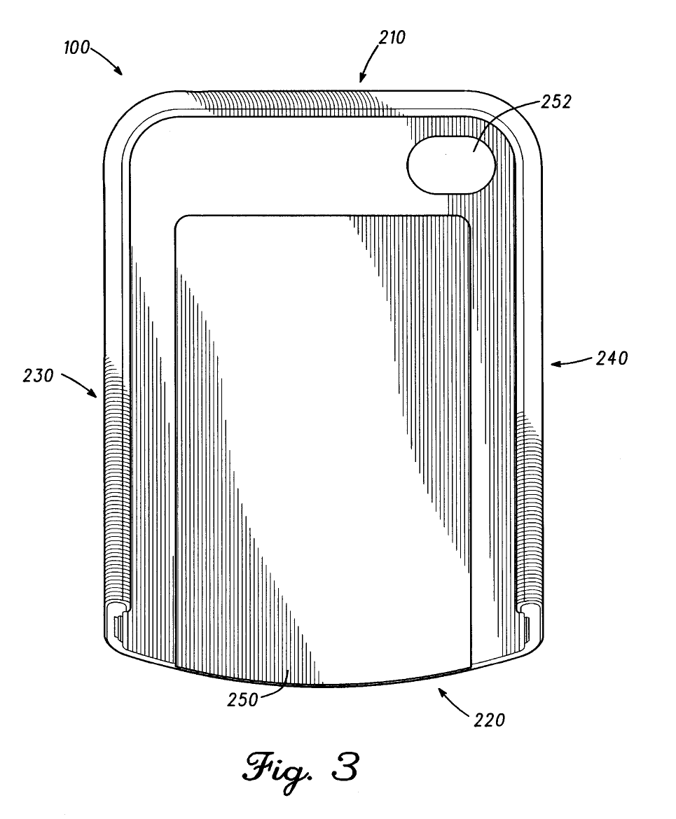

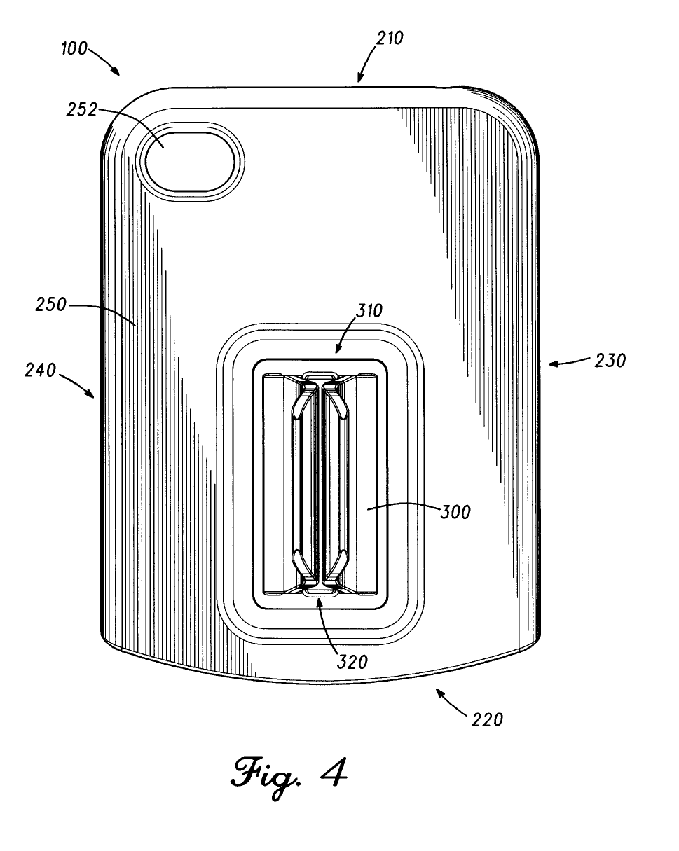

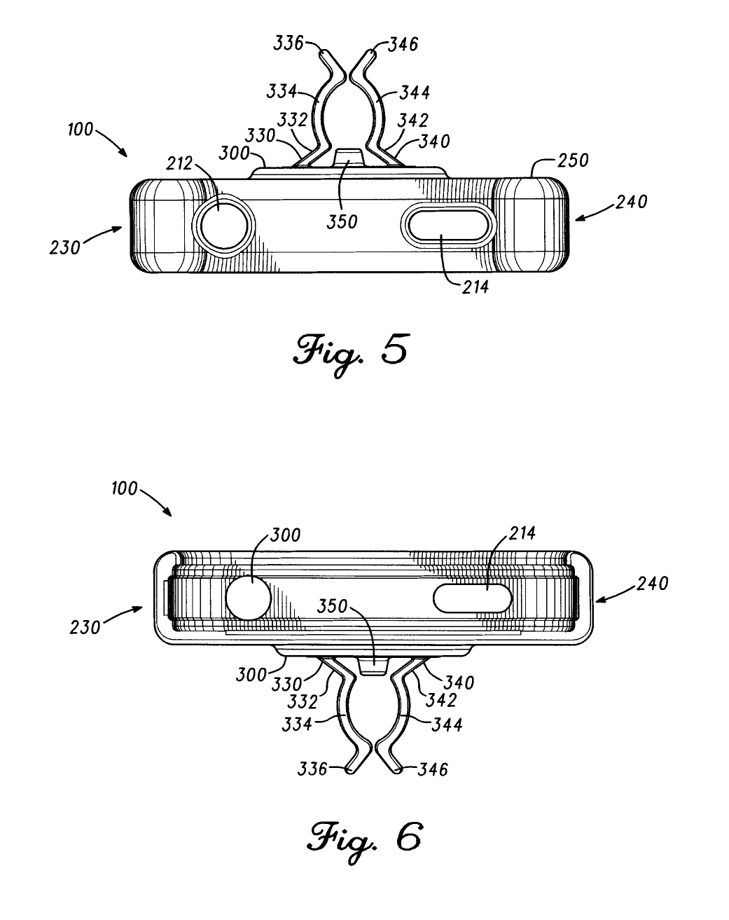

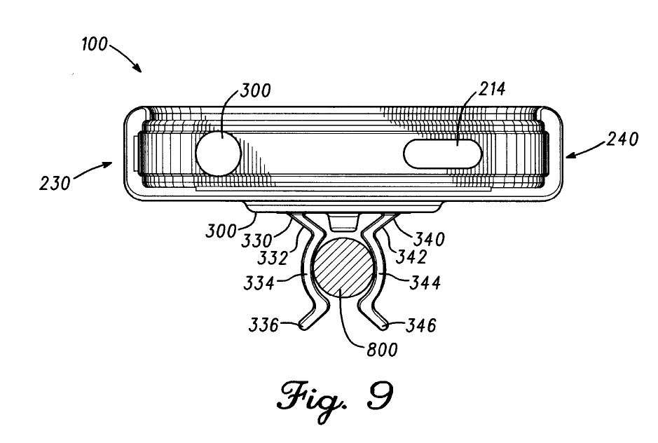

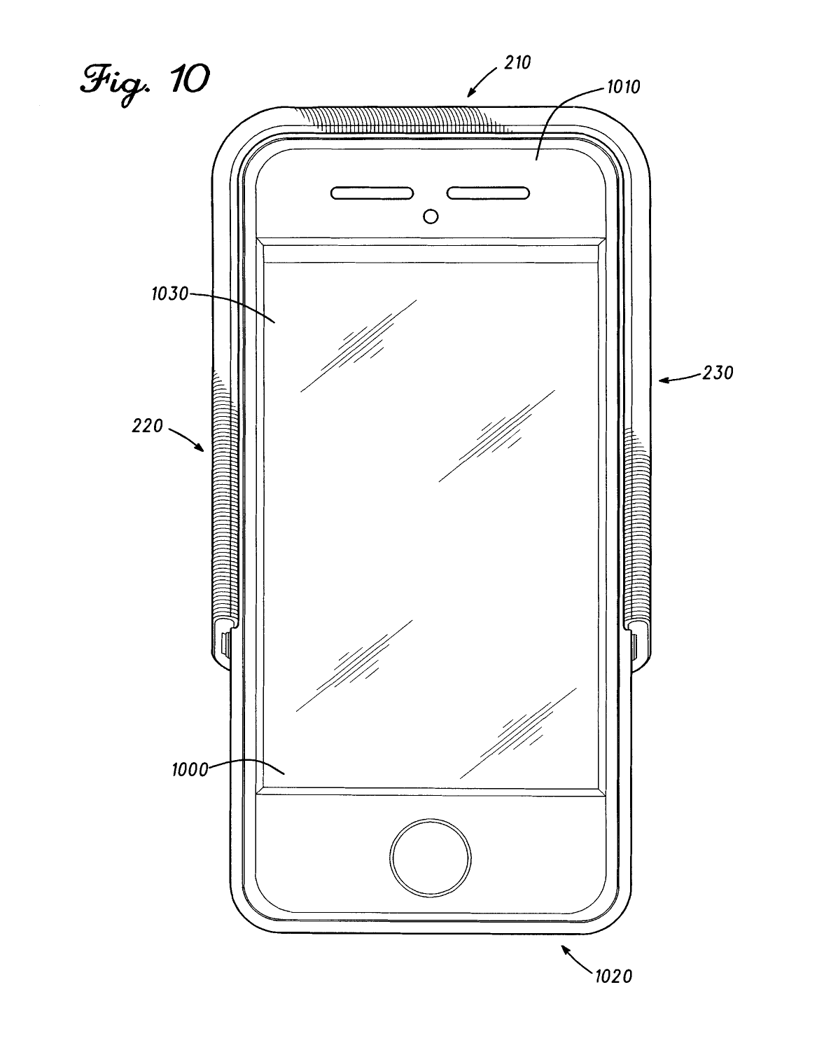

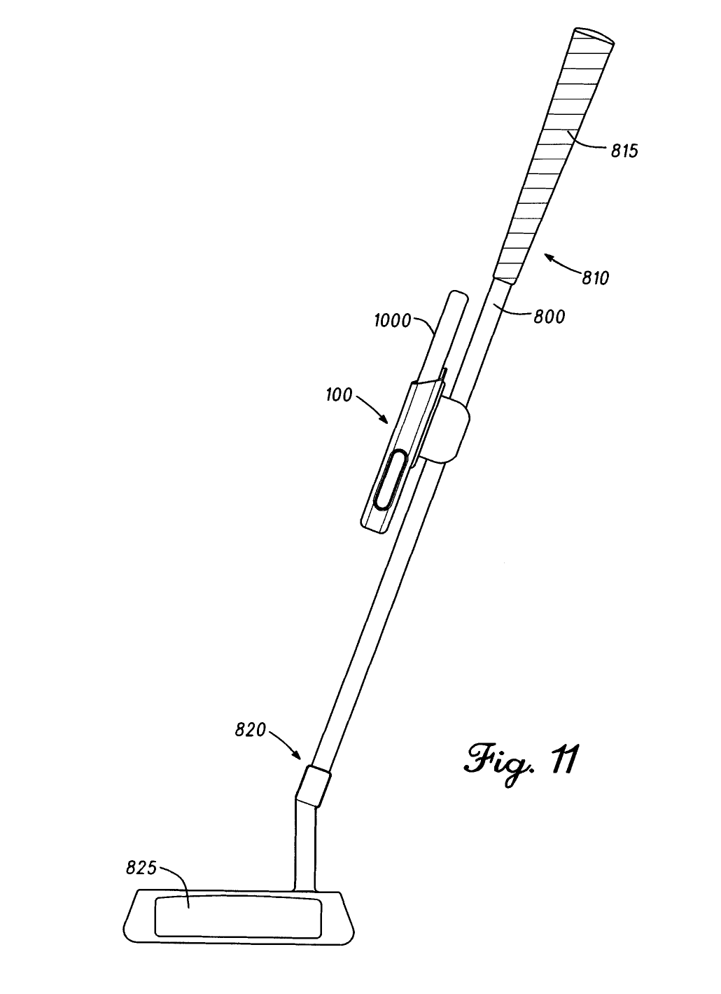

In the example of FIGS. 1-11, a portable electronic device holder 100 may include a body portion 200 (e.g., generally shown in FIG. 2) and a clamp portion 300 (e.g., generally shown in FIG. 3). As described in detail below, the portable electronic device holder 100 may be configured to removably attach and secure a portable electronic device (e.g., one generally shown as 1000 in FIG. 10) such as a wireless communication device and/or a portable media player to a golf club shaft (e.g., one generally shown as 800 in FIGS. 8 and 9) of a golf club (e.g., a putter-type golf club). For example, the portable electronic device 1000 may be a media player (e.g., an IPOD® mobile digital device from Apple Inc., Cupertino, Calif.), a wireless telephone (e.g., an IPHONE® mobile digital device from Apple Inc., Cupertino, Calif.), a handheld computer, a global positioning system (GPS) device, a game console device, a digital camera and/or a video camera. As described in detail below, the portable electronic device 1000 may be configured to operate as a training device and/or a gaming device (e.g., the portable electronic device 1000 may include a processor to execute a software application). In addition or alternatively, the portable electronic device 1000 may be configured to operate as a telephone or a speaker broadcasting music. The apparatus and articles of manufacture described herein are not limited in this regard.

In particular, the body portion 200 of the portable electronic device holder 100 may include a first body end 210, a second body end 220, a first side portion 230, a second side portion 240, and a back portion 250. One or more portions of the body portion 200 may include one or more openings to accommodate for buttons, switches, ports, etc. of the portable electronic device 1000, generally shown as 212, 214, 222, and 232. In one example, the first body end 210 may include an opening 212 to accommodate a headphone jack and an opening 214 to accommodate a power switch of the portable electronic device 1000. The second body end 220 may include an opening 222 to receive the portable electronic device 1000. The first side portion 230 may include an opening 232 to accommodate one or more buttons to control volume. The back portion 250 may include an opening to accommodate a camera lens. The body portion 200 may be made of semi-rigid molded plastic or other suitable type materials. For example, the body portion 200 may be made of polycarbonate material and/or polypropylene material. The apparatus and articles of manufacture described herein are not limited in these regards.

In general, the portable electronic device 1000 may be able to slide in and out the body portion 200 via the opening 222 of the second body end 220. The first body end 210, the second body end 220, the first side portion 230, the second side portion 240, and the back portion 250 may be configured to secure the portable electronic device 900 so that the portable electronic device 1000 does not slide out from the body portion 200 without being pulled away from the portable electronic device holder 100. For example, the first body end 210, the first side portion 230, and/or the second side portion 240 may be curved or contoured in a manner to accommodate the outer shape of the portable electronic device 1000. The back portion 250 may include a material, which helps to retain the portable electronic device 1000 in the body portion 200 via friction. While the above examples may describe various openings at or proximate to particular portions, the apparatus, the methods, and the articles of manufacture described herein are not limited in this regard.

The clamp portion 300 may include a first clamp end 310, a second clamp end 320, a first arm portion 330, and a second arm portion 340. Each of the first and second arm portions 330 and 340 may have a W-shaped configuration. In particular, the first arm portion 330 may include a first support portion 332, a first arcuate portion 334, and a first guide portion 336. The first support portion 332 of the first arm portion 330 may extend from the back portion 240 of the body portion 200. The first support portion 332 may be coupled to the first arcuate portion 334, which in turn, may be coupled the first guide portion 336.

In a similar manner, the second arm portion 340 may include a second support portion 342, a second arcuate portion 344, and a second guide portion 346. The second support portion 342 of the second arm portion 340 may extend from the back portion 250 of the body portion 200. The second support portion 342 may be coupled to the second arcuate portion 344, which in turn, may be coupled the second guide portion 346.

The clamp portion 300 may be made of a semi-rigid material such as plastic and/or other suitable type of materials. For example, the clamp portion 300 may be made of polycarbonate material and/or polypropylene material. The first and second guide portions 336 and 346 may be configured to assist the golf club shaft 800 to engage the first and second arcuate portions 334 and 344. The first and second support portions 332 and 342 may be configured to provide flexibility so that the clamp portion 300 may engage the golf club shaft 800.

In one example as shown in FIG. 9, the first and second arcuate portions 334 and 344 may be configured to engage the golf club shaft 800 (i.e., a cross-sectional view of the golf club shaft 800 is shown). The first and second arcuate portions 334 and 344 may be configured to engage golf club shafts with various diameter size. For example, the first and second arcuate portions 334 and 344 may be configured to engage golf club shafts having a diameter of at least 0.3 inches. With some golf club shafts taper from one end to another (e.g., 0.335 inches at the tip end and 0.6 inches at the butt end), the first and second arcuate portions 334 and 344 may be configured to engage golf club shafts having a diameter ranging from 0.4 inches to 0.6 inches. The apparatus, the methods, and the articles of manufacture described herein are not limited in this regard.

The clamp portion 300 may also include a bumper portion 350. In particular, a portion of the golf club shaft 800 may rest against the bumper portion 350. The bumper portion 350 may prevent or reduce damage to the graphics of the golf club shaft 800 and/or the golf club shaft 800 itself.

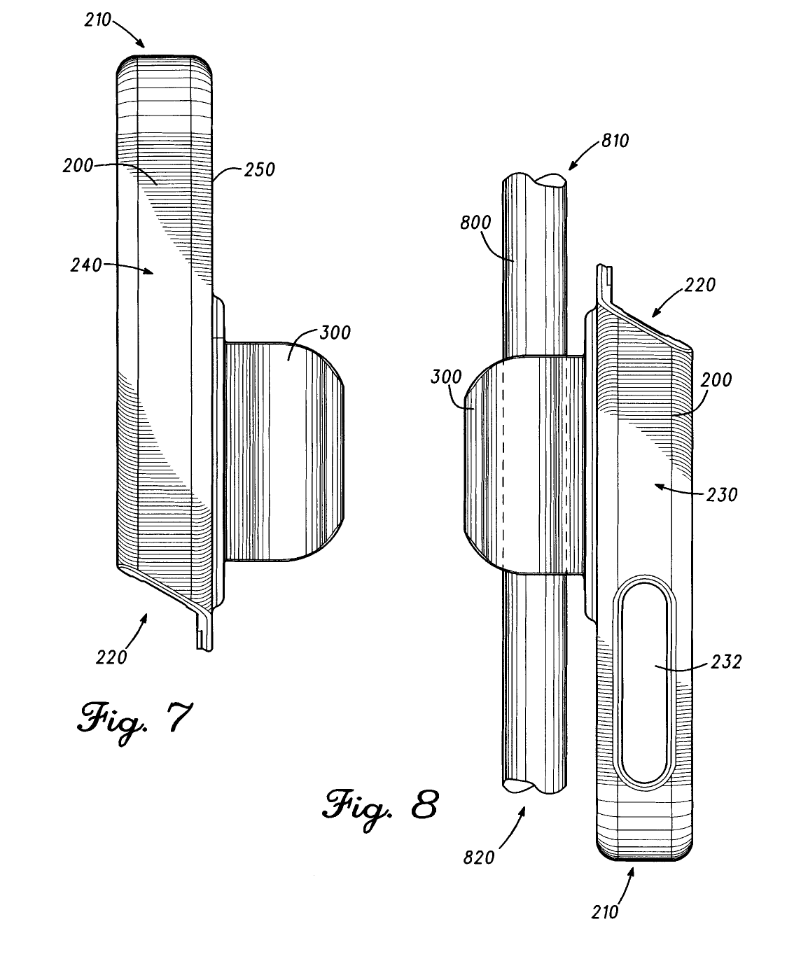

In the example of FIGS. 8-11, the golf club shaft 800 may include a butt end 810 and a tip end 820. A grip 815 may be located at or proximate to the butt end 810 whereas a golf club head 825 may be located at or proximate to the tip end 820. The portable electronic device holder 100 may engage the golf club shaft 800 of a golf club at or proximate to the butt end 810. To engage the golf club shaft 800, the portable electronic device holder 100 may be rotated 180 degrees from the orientation of the portable electronic device holder 100 shown in FIG. 7. As shown in FIG. 8, for example, the first end portion 210 of the portable electronic device holder 100 may point towards the tip end 820 of the golf club shaft 800 whereas the second end portion 220 of the portable electronic device holder 100 may point towards the butt end 810 of the golf club shaft 800. The apparatus, the methods, and the articles of manufacture described herein are not limited in this regard.

In the example of FIG. 10, a portable electronic device 1000 may include a top portion 1010, a bottom portion 1020, and a display portion 1030. The body portion 200 of the portable electronic device holder 100 may receive the portable electronic device 1000. In particular, the top portion 1010 of the portable electronic device 1000 may slide through the opening 222 of the second body end 220. The first body end 210 of the body portion 200 may be configured to abut the top portion 1010 of the portable electronic device 1000. The portable electronic device holder 100 may include an opening so that the display portion 1030 of the portable electronic device 1000 may be visible. In one example, the portable electronic device 1000 may operate as a training device for golf. Accordingly, any visual representation may be generated on the display portion 1030, which can be seen by an individual while the portable electronic device 1000 is secured to the portable electronic device holder 100. The apparatus, and the articles of manufacture described herein are not limited in this regard.

While the above examples may be described in connection with a putter-type golf club, the apparatus and articles of manufacture described herein may be applicable to other types of golf club such as a driver-type golf club, a fairway wood-type golf club, a hybrid-type golf club, an iron-type golf club, or a wedge-type golf club. Alternatively, the apparatus and articles of manufacture described herein may be applicable other types of sports equipment such as a hockey stick, a tennis racket, a fishing pole, a ski pole, etc.

Although certain example methods, apparatus, and/or articles of manufacture have been described herein, the scope of coverage of this disclosure is not limited thereto. On the contrary, this disclosure covers all methods, apparatus, and/or articles of manufacture fairly falling within the scope of the appended claims either literally or under the doctrine of equivalents.

What is claimed is:

1. A portable electronic device holder comprising:
a body portion configured to hold a portable electronic device configured to detect motion of a golf club; and
a clamp portion coupled to the body portion, the clamp portion being configured to removably attach the portable electronic device holder to a shaft of the golf club.

2. A portable electronic device holder as defined in claim 1, wherein the clamp portion comprises a clamp portion integral to the body portion.

3. A portable electronic device holder as defined in claim 1, wherein the clamp portion comprises a clamp portion removable from the body portion.

4. A portable electronic device holder as defined in claim 1, wherein the clamp portion comprises a first arm portion and a second arm portion.

5. A portable electronic device holder as defined in claim 1, wherein the clamp portion comprises an arm portion having a support portion, an arcuate portion, and a guide portion.

6. A portable electronic device holder as defined in claim 1, wherein the clamp portion comprises a rest portion to engage a portion of the shaft.

7. A portable electronic device holder as defined in claim 1, wherein the clamp portion comprises an inner circumference substantially equal to an outer circumference of the shaft.

8. A portable electronic device holder as defined in claim 1, wherein the clamp portion comprises a clamp portion configured to removably attach the portable electronic device holder to a grip end of the shaft of the golf club.

9. A portable electronic device holder as defined in claim 1, wherein the body portion comprises one or more openings to access at least one of a switch, a button, or a port of the portable electronic device.

10. A portable electronic device holder as defined in claim 1, wherein the portable electronic device holder comprises at least one of polycarbonate material or polypropylene material.

11. A portable electronic device holder as defined in claim 1, wherein the portable electronic device comprises at least one of a media player, a wireless telephone, a gaming console, or a handheld computer.

12. An apparatus comprising:
a body portion configured to hold a portable electronic device configured to detect motion of sports equipment; and
a clamp portion removably coupled to the body portion, the clamp portion being configured to removably attach the body portion to a portion of sports equipment,
wherein the portable electronic device comprises at least one of a media player, a wireless telephone, a gaming console, or a handheld computer.

13. An apparatus as defined in claim 12, wherein the portion of sports equipment comprises a shaft of a golf club.

14. An apparatus as defined in claim 12, wherein the clamp portion comprises a clamp portion configured to removably attach the portable electronic device holder to a grip end of the shaft of the golf club.

15. An apparatus as defined in claim 12, wherein at least one of the body portion or the clamp portion comprises at least one of polycarbonate material or polypropylene material.

16. A system comprising:
a first portion configured to hold a portable electronic device configured to detect motion of a golf club; and
a second portion removably coupled to the first portion, the second portion being configured to removably attach the first portion to a shaft of the golf club.

17. A system as defined in claim 16, wherein at least one of the first portion or the second portion comprises at least one of polycarbonate material or polypropylene material.

18. A system as defined in claim 16, wherein the second portion configured to removably attach the first portion to a grip end of the shaft of the golf club.

19. A system as defined in claim 16, wherein the golf club comprises a putter-type golf club.

20. A system as defined in claim 16, wherein the portable electronic device comprises at least one of a media player, a wireless telephone, a gaming console, or a handheld computer.
